(19) United States
(12) Patent Application Publication
(10) Pub. No.: US 2005/0158913 A1
(43) Pub. Date: Jul. 21, 2005

(54) Solid state imaging apparatus and its manufacturing method

(75) Inventors: Toshiaki Kouda, Kurokawa-gun (JP); Takeshi Nishida, Kurokawa-gun (JP); Syu Yamada, Kurokawa-gun (JP)

Correspondence Address: ARENT FOX PLLC, 1050 CONNECTICUT AVENUE, N.W., SUITE 400, WASHINGTON, DC, 20036, US

(73) Assignee: FUJI PHOTO FILM CO., LTD.

(21) Appl. No.: 11/036,358

(22) Filed: Jan. 18, 2005

(30) Foreign Application Priority Data
Jan. 19, 2004 (JP) 2004-010461
Jan. 29, 2004 (JP) 2004-021506

(51) Int. Cl. H01L 21/44

(52) U.S. Cl. 438/113

(57) ABSTRACT

A manufacturing method of a solid state imaging apparatus comprises the steps of preparing a semiconductor wafer on which a plurality of solid state imaging devices are formed, grinding an opposite side of a surface of the semiconductor wafer where the solid state imaging devices are formed, attaching the back grinded semiconductor wafer to a dicing ring via a dicing tape, performing a hydrophilicizing process to the back grinded semiconductor wafer attached to the dicing ring and to an adhesive of the dicing tape, dicing the hydrophilicized semiconductor wafer by a dicing blade and removing adhering material appeared by the dicing by performing rinsing that gives a low damage to the solid state imaging device. The manufacturing method of a solid state imaging apparatus wherein a dicing process can be performed without decreasing an optical property of a solid state imaging device can be provided.

### CROSS REFERENCE TO RELATED APPLICATION

This application is based on Japanese Patent Application 2004-010461, filed on Jan. 19, 2004 and Japanese Patent Application 2004-021506, filed on Jan. 29, 2004, the entire contents of which are incorporated herein by reference.

### BACKGROUND OF THE INVENTION

A) Field of the Invention

This invention relates to a manufacturing method of a solid state imaging apparatus, and more specifically relates to a dicing method of a solid state imaging device and a wire-bonding method of a solid state imaging device and a package for containing the solid state imaging device.

B) Description of the Related Art

A solid state imaging device is diced by cutting a semiconductor wafer with a dicing blade of a dicing device after setting the semiconductor wafer onto a dicing ring with a dicing tape adhered on the dicing ring. At the time of cutting, cutting waste is appeared, and to obtain cleanness by rinsing out the cutting waste by using massive pure water.

Conventionally, a wire-bonding process for a solid state imaging device and a package for containing the solid state imaging device is generally performed by wiring a pad area of the solid state imaging device and a inner-lead area of the package with a metal wire or the likes after adhering a semiconductor chip (the solid state imaging device) which is obtained by dicing a semiconductor wafer to the package made of ceramics or the likes for containing the semiconductor chip with a silver paste or the likes.

Moreover, when rinsing out the cutting waste with massive pure water, a dry region may be appeared on the semiconductor wafer, and the cutting wafer may be adhered to the dry region. In order to get rid of the dry region, it is well known that a surface of a semiconductor wafer is hydrophilicized by a plasma treatment is performed to the surface of the semiconductor wafer (e.g., refer to Japanese Patent Application Laid-Open No. Hei 05-335412).

In the conventional dicing method of a solid state imaging device, there are many chances of that cutting waste appeared at the time of cutting a semiconductor wafer is adhered on a solid state imaging device, and it may cause an image defection after assembling the solid state imaging device.

Moreover, there is a chance of that an adhesive of a dicing tape which is exposed at the time of cutting the semiconductor wafer is peeled off from the dicing tape by the massive pure water and adhered on the solid state imaging device. This adhesive may be one of the reasons for an image defection of the solid state imaging device.

For removing these adhering materials from the solid state imaging device, a high-pressure water rinsing process by using massive pure water is necessary; however, the high-pressure water rinsing gives a great damage to a solid state imaging device, especially to a light-receiving region.

Depending on a manufacturing method of a semiconductor wafer, an organic thin-film layer may be formed, by remained organic materials for forming micro lenses or by deposition of an outgas before an assembly, on a wiring layer of the pad area of the solid state imaging device where a wire bonding (e.g., a gold wire, an aluminum wire, etc.) is connected.

If the wire bonding process is performed with the organic thin-film layer being formed on the wiring layer of the pad area of the solid state imaging device, sufficient wire contacting strength cannot be obtained because of an influence of the organic thin-film layer. Therefore, the organic thin-film layer should be removed before performing the wire bonding process. However, if the organic thin-film layer is removed after dicing the semiconductor wafer, a number of processes will be increased to hundreds or thousands times comparing if it is performed before the dicing process, and it decreases productivity.

### SUMMARY OF THE INVENTION

It is an object of the present invention to provide a manufacturing method of a solid state imaging apparatus wherein a dicing process can be performed without decreasing an optical property of a solid state imaging device.

Moreover, It is another object of the present invention to provide a manufacturing method of a solid state imaging apparatus that has a good productivity.

Furthermore, it is still another object of the present invention to provide a manufacturing method of a solid state imaging apparatus that can improve an electrical reliability.

According to one aspect of the present invention, there is provided A manufacturing method of a solid state imaging apparatus comprising the steps of (a) preparing a semiconductor wafer on which a plurality of solid state imaging devices are formed, (b) grinding an opposite side of a surface of the semiconductor wafer where the solid state imaging devices are formed, and (c) dicing the back grinded semiconductor wafer by a dicing blade and removing adhering material appeared by the dicing by performing rinsing that gives a low damage to the solid state imaging device.

Moreover, according to another aspect of the present invention, there is provided A manufacturing method of a solid state imaging apparatus comprising the steps of (a) preparing a semiconductor wafer on which a plurality of solid state imaging devices are formed, (b) attaching the semiconductor wafer to a dicing ring via a dicing tape, (c) performing a hydrophilicizing process to the semiconductor wafer attached to the dicing ring and to an adhesive of the dicing tape, and (d) dicing the hydrophilicized semiconductor wafer by a dicing blade and removing adhering material appeared by the dicing by performing rinsing that gives a low damage to the solid state imaging device.

According to the present invention, a manufacturing method of a solid state imaging apparatus wherein a dicing process can be performed without decreasing an optical property of a solid state imaging device can be provided.

Furthermore, according to still another aspect of the present invention, there is provided A manufacturing method of a solid state imaging apparatus comprising the steps of (a) preparing a semiconductor wafer on which a plurality of solid state imaging devices each having a pad area for connecting a wire bonding are formed, (b) performing an organic thin-film layer removing process for removing an organic thin-film layer disposed on the pad area to the semiconductor wafer, (c) dicing the semiconductor wafer after the organic thin-film layer removing step (b), (d) connecting each one of the plurality of the solid state imaging devices diced at the dicing step (c) to a package having an inner-lead area, and (e) connecting the pad area of each solid state imaging device and the inner lead area of each package by wire bonding.

According to the present invention, a manufacturing method of a solid state imaging apparatus that has a good productivity can be provided.

Moreover, according to the present invention, a manufacturing method of a solid state imaging apparatus that can improve an electrical reliability can be provided.

### BRIEF DESCRIPTION OF THE DRAWINGS

FIGS. 1A and 1B are diagrams for explaining a dicing method according to a first embodiment of the present invention.

FIG. 2 is a plan view showing a semiconductor wafer 1 attached to a dicing ring 2.

FIG. 3 is a cross sectional view for explaining a hydrophilicizing process to the semiconductor wafer 1.

FIG. 4 is a diagram for explaining a dicing process of the semiconductor wafer 1.

FIGS. 5A and 5B are diagrams for explaining a wire bonding method of a solid state imaging device and a package according to a second embodiment of the present invention.

FIGS. 6A and 6B are cross sectional views for explaining an organic thin-film layer removing process to the semiconductor wafer 1 according to the second embodiment of the present invention.

FIG. 7 shows a wire bonding process according to the second embodiment of the present invention.

FIGS. 8A and 8B are graphs showing measurement results of connection strength of a wire bonding 21 made of a gold wire after the organic thin-film layer removing process according to the second embodiment of the present invention.

### DETAILED DESCRIPTION OF THE PREFERRED EMBODIMENTS

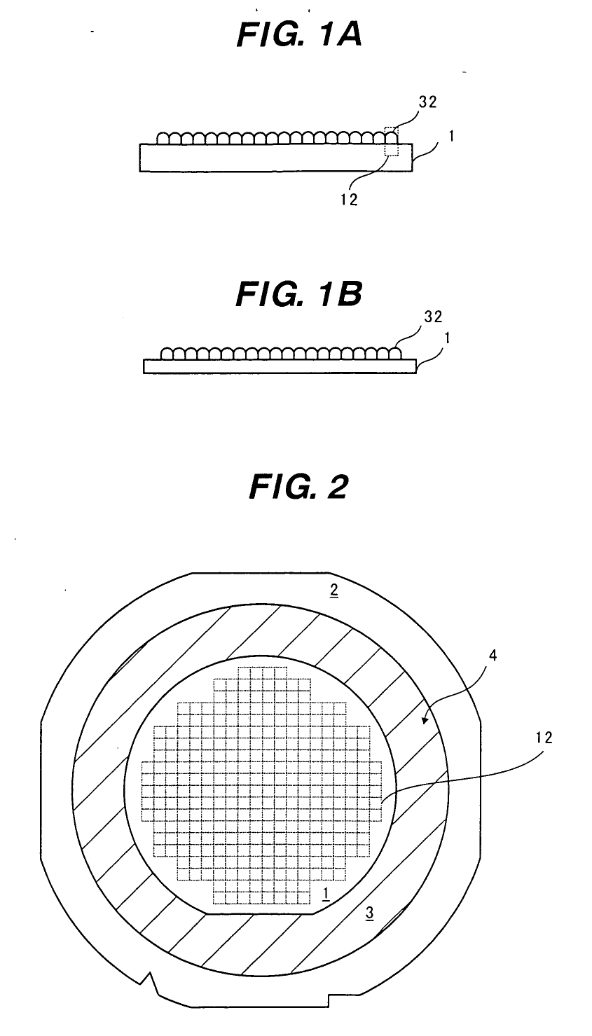

FIGS. 1A and 1B are diagrams for explaining a dicing method according to a first embodiment of the present invention.

FIG. 1A is a cross sectional view showing a semiconductor wafer 1 before a back grind process according to the first embodiment of the present invention.

The semiconductor wafer 1 is, for example, a silicon wafer having a diameter of 6 inches and a thickness of 500 μm. On the semiconductor wafer 1, solid state imaging devices 12 are formed in a plurality of rows and columns.

The solid state imaging device 12 is, for example, a CCD type solid state imaging device, and has a light receiving region including at least a multiplicity of photoelectric conversion elements, vertical electric charge transferring devices (a vertical charge coupled device: VCCD) each of which vertically transfers electric charges generated by each column of the photoelectric conversion elements and a micro lens 32 formed above each of the multiplicity of the photoelectric conversion elements, a horizontal electric charge transferring device (a horizontal charge coupled device: HCCD) that horizontally transfers the electric charges transferred by the VCCD, and a peripheral circuit including an output amplifier, etc. Further, the solid state imaging device 12 may be a MOS type solid state imaging device or the likes.

Each micro lens 32 is formed on a surface of the solid state imaging device 12 corresponding to each one of the multiplicity of the photoelectric conversion elements formed on the solid state imaging device 12. The micro lens 32 is, for example, formed by re-flowing a transparent resin layer formed on a planarizing layer and patterned to a predetermined shape by the photolithography or the likes.

In this first embodiment, before a dicing process, the semiconductor wafer 1 is set to a back grind device to perform a back grind, for example, of 300 μm or less to a back side of the semiconductor wafer 1 (an opposite side of the surface where the solid state imaging devices 12 are formed). By this back grind process, the semiconductor wafer 1 will be a condition shown in FIG. 1B, and will have a thickness of, for example, 300 μm.

As described in the above, by making the thickness of the semiconductor wafer 1 thin before the dicing process, cutting groove 6 (FIG. 4) at the dicing process can be shallow and therefore cutting waste appeared at the time of the dicing process can be reduced. Therefore, cutting waste adhered onto the solid state imaging device 12 can be reduced.

Next, the semiconductor wafer 1 shown in FIG. 1B to which the back grind process is performed will be attached to a dicing ring 2 via a dicing tape 3 to make it a condition shown in FIG. 2.

FIG. 2 is a plan view showing a semiconductor wafer 1 attached to a dicing ring 2. Cutting grooves indicated by dotted lines between each solid state imaging device 12 in the semiconductor wafer 1 have not been formed at this time. Adhesive 4 of the dicing tape 3 is exposed in an area indicated by slanted lines in the drawing between the dicing ring and the semiconductor wafer 1. If the dicing process is performed in this condition, the exposed adhesive 4 may be dissolved by rinsing water in the dicing process and get on the surface of the solid state imaging device 12. Therefore, in this first embodiment, a hydrophilicizing process is performed to the semiconductor wafer 1 attached to the dicing ring 2.

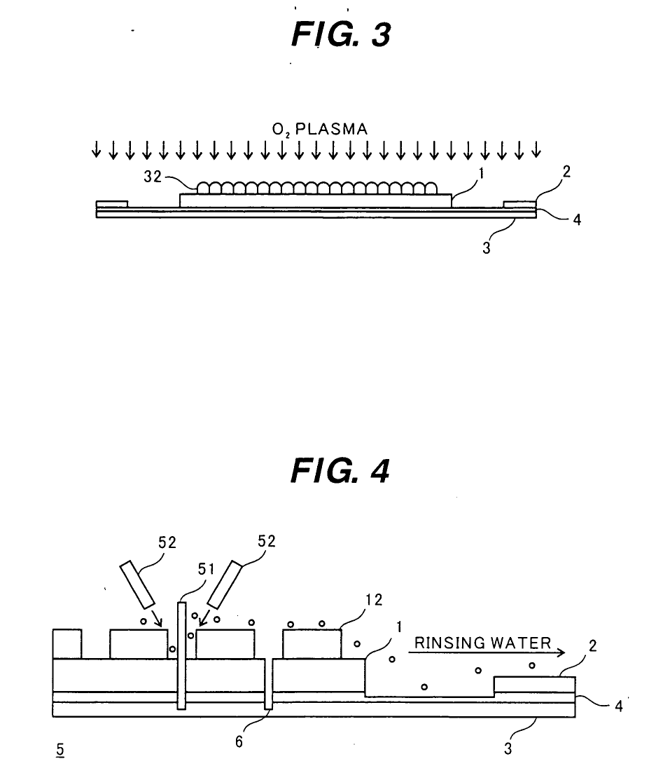

FIG. 3 is a cross sectional view for explaining the hydrophilicizing process to the semiconductor wafer 1.

First, the semiconductor wafer 1 attached to the dicing ring 2 is set to a reduced pressure O₂ plasma chamber to be hydrophilicized. The plasma process is executed under a condition having, for example, a high frequency power source output of 50(W) at 13.56 MHz, a vacuum rate in the chamber for 20 (Torr) and a gas-flow rate at 10 (mVmin). Under this condition, plasma treatment time will be, for example, 10 (sec).

By performing the plasma process under the above-described condition, a part of the exposed adhesive 4 of the dicing ring 3 can be removed, and a surface of the remaining adhesive 4 can be hydrophilicized. Although it is preferable that all of the adhesive 4 are removed by the above-described plasma process, a part of the adhesive 4 is removed and the remaining part is hydrophilicized instead of removing the all from the necessity of keeping an optical property of the micro lenses 32 formed on the surface of the solid state imaging device 12 as described in the below in this first embodiment. That is, if an optical property of the micro lenses 32 can be maintained, the plasma process can be performed under plasma condition enough for removing the entire adhesive 4.

By the above-described plasma process, the hydrophilicizing process is simultaneously executed to the micro lenses 32 formed on the solid state imaging device 12. Each of the micro lenses 32 has, for example, a height of about 1 μm and a diameter of about 3 μm. Under the above-described plasma condition, surfaces of the micro lenses 32 are etched about 0.03 μm; however, it is about 3% of the height of the microlenses 32. Therefore, the plasma process has almost no influence on an optical property of the micro lenses 32.

Moreover, under a plasma condition harder than the above-described plasma condition, the process may cause, by a rapid reaction, deteriorations of an optical property of the micro lenses 32 and an electrical property of the solid state imaging device 12 which are influences of the process other than desired influences such as removing or hydrophilicizing the exposed part of the adhesive 4 of the dicing tape 3 and hydrophilicizing the surfaces of the micro lenses 32 which are the objects of the plasma process in the first embodiment. Therefore, the plasma process according to the first embodiment is necessary to be a low damage plasma condition such as the above-described plasma condition. In this specification, the low damage plasma condition is, for example, a condition wherein organic material is not etched more than 300 angstrom. Further, a gas used in the plasma process is not limited to the above-described O₂ gas but also be a mixed gas of O₂ and Ar.

Furthermore, the above-described hydrophilicizing process is not limited to the plasma process. For example, the adhesive 4 and the microlenses 32 are hydrophilicized by changing surface characteristics by an optical ozone technique using ultraviolet radiation (UV) and ozone (O₃).

In a normal state, the adhesive 4 does not have a hydrophilic group and repels rinsing water at the time of the dicing process; therefore, the adhesive 4 may adhere to the semiconductor wafer 1 when the adhesive 4 is flown out by a physical pressure. However, by performing the above-described hydrophilicizing process to change the surface character of the adhesive 4 for hydrophilicizing and not to repel rinsing water, cleanness of the semiconductor wafer 1 can be improved. Moreover, the surface character of the micro lenses 32 is also changed to be hydrophilic, and therefore adhered pollutants can be rinsed out without a high physical pressure.

FIG. 4 is a diagram for explaining the dicing process of the semiconductor wafer 1. In the drawing, white circles represent cutting waste or other pollutants.

In this dicing process, first, the semiconductor wafer 1 after the hydrophilicizing process shown in FIG. 3 is set to a dicing device 5. The dicing device 5 includes at least a dicing blade 51 and a mega sonic rinsing nozzle 52 configured near the dicing blade 51. The mega sonic rinsing nozzle 52 includes an oscillator that gives an oscillation of over mega hertz (MHz) to rinsing water such as pure water, etc. and emits the oscillated rinsing water to the surface of the semiconductor wafer 1.

The dicing device 5 forms cutting grooves 6 to a direction of thickness of the semiconductor wafer 1 by the dicing blade 51. The cutting grooves 6 are formed between each column of the solid state imaging devices 12 and between each row of the solid state imaging devices 12 (refer to the dotted lines inside the semiconductor wafer 1 shown in FIG. 2). Because cutting waste is appeared by this cutting, the appeared cutting waste and other pollutants (e.g., flown-out adhesive 4, etc.) are rinsed out from the semiconductor wafer 1 by emitting the rinsing water oscillated over mega hertz (MHz) from the mega sonic rinsing nozzle 52 to the semiconductor wafer 1.

Further, rinsing of the semiconductor wafer 1 in the dicing process is not only performed by using the mega sonic rinsing nozzle 52, but also by anything that has a small physical pressure and does not give a damage on the solid state imaging devices 12 formed on the semiconductor wafer 1. For example, the rinsing of the semiconductor wafer 1 is performed with a two-fluid rinsing nozzle using pure water and air.

After performing the above-described back grind process, hydrophilicizing process and dicing process, division of chips, packaging, etc. will be performed. The division of chips, packaging, etc. may be performed by using a well-known technique.

According to the above-described first embodiment of the present invention, a thickness of the semiconductor wafer 1 is thinned by the back grind process before the dicing process, depth of the cutting grooves 6 necessary for dicing can be shallow. Therefore, cutting by the dicing blade 51 can be shallow and cutting waste appeared by the cutting can be reduced. Moreover, because the cutting groove 6 can be shallow, removal of cutting waste inside the cutting grooves 6 will be easy.

Further, according to the above-described first embodiment of the present invention, by making the exposed surface of the adhesive 4 hydrophilic, adhesion of the adhesive 4 to the semiconductor wafer 1 can be reduced. It is considered that an amount of the flown-out adhesive 4 is reduced because a part of the adhesive 4 is removed by the hydrophilicizing process.

Furthermore, according to the above-described first embodiment of the present invention, the surfaces of the micro lenses 32 are also made to be hydrophilic; therefore, adhesion of the cutting waste, adhesive 4 and other pollutants can be reduced. Moreover, when the pollutants, etc. are adhered to the surfaces of the micro lenses 32, removal of the pollutants or the likes becomes easy.

Also, according to the above-described first embodiment of the present invention, pollutants or the likes from the outside of the semiconductor wafer 1 can be extremely reduced by the back grind process and the hydrophilicizing process, and the surfaces of the solid state imaging devices 12 (the surfaces of the micro lenses 32) is also hydrophilicized; therefore, it is not necessary for the dicing process to have high ability of rinsing. Therefore, a rinsing method giving a lower damage to the solid state imaging devices 12, for example, rinsing by the mega sonic rinsing becomes possible. That is, in this first embodiment, the back grind process and the hydrophilicizing process are performed before the dicing process; therefore, large adhering pollutants can be incredibly reduced and a rinsing method giving a high damage to the solid state imaging devices 12 for removing the large pollutants will be unnecessary. As a result, high cleanness can be obtained by the rinsing method giving lower damage suited for removing small pollutants such as the mega sonic rinsing.

Moreover, according to the above-described first embodiment of the present invention, by performing the back grind process and the hydrophilicizing process before the dicing process, an image defection caused by adherence of cutting waste and other pollutants to the solid state imaging device 12 can be exceedingly reduced.

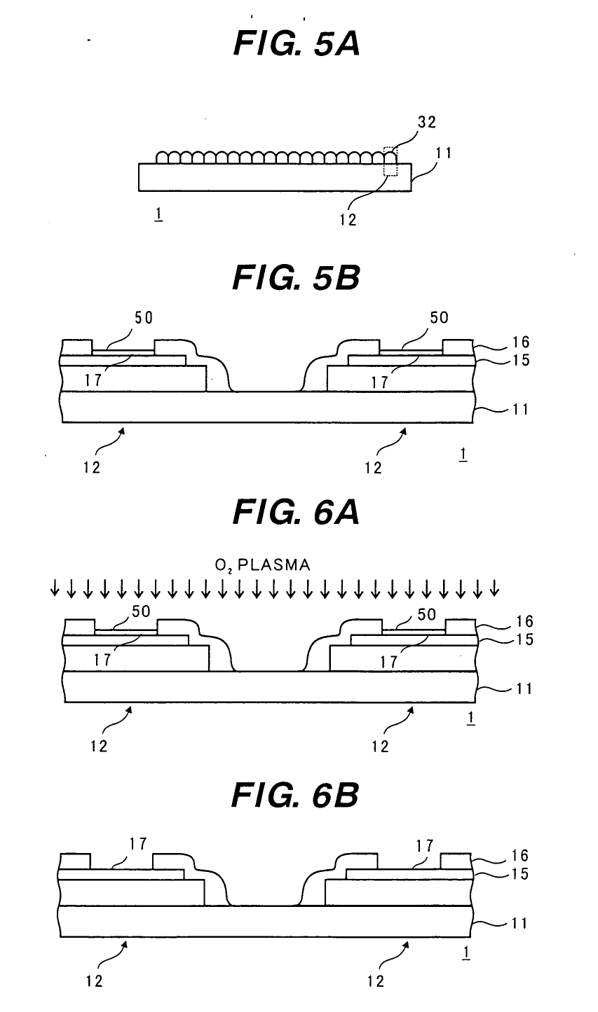

FIGS. 5A and 5B are diagrams for explaining a wire bonding method of a solid state imaging device and a package according to a second embodiment of the present invention.

FIG. 5A is a cross sectional view showing a semiconductor wafer 1 before a plasma process according to the second embodiment of the present invention.

The semiconductor wafer 1 is, for example, a silicon wafer having a diameter of 6 inches and a thickness of 500 μm. On the semiconductor wafer 1, solid state imaging devices 12 are formed in a plurality of rows and columns.

The solid state imaging device 12 is, for example, a CCD type solid state imaging device, and has a light receiving region including at least a multiplicity of photoelectric conversion elements, vertical electric charge transferring devices (a vertical charge coupled device: VCCD) each of which vertically transfers electric charges generated by each column of the photoelectric conversion elements and a micro lens 32 formed above each of the multiplicity of the photoelectric conversion elements, a horizontal electric charge transferring device (a horizontal charge coupled device: HCCD) that horizontally transfers the electric charges transferred by the VCCD, and a peripheral circuit including an output amplifier, etc. Further, the solid state imaging device 12 may be a MOS type solid state imaging device or the likes.

Each micro lens 32 is formed on a surface of the solid state imaging device 12 corresponding to each one of the multiplicity of the photoelectric conversion elements formed on the solid state imaging device 12. The micro lens 32 is, for example, formed by re-flowing a transparent resin layer formed on a planarizing layer and patterned to a predetermined shape by the photolithography or the likes.

FIG. 5B is a partial enlarged side view of a bonding pad 17 of each solid state imaging device 12 formed on the semiconductor wafer 1 shown in FIG. 1A.

At an edge of the solid state imaging device 12, edges 14 of various inter-layer insulating films are extended on a semiconductor substrate 11, and a wiring layer 15 made of aluminum (Al) or the likes is formed on the edges 14 of various inter-layer insulating films. On the wiring layer 15, an insulating layer 16 made of silicon nitride (SiN) or the likes is formed. In the insulating layer 16, an opening is formed, and a surface of the wiring layer 15 is exposed through the opening. This exposed surface of the wiring layer 15 is used as a pad area 17 for connecting a wire bonding. On the pad area 17, an organic thin-film layer 50 formed of remains of organic material at the tie of forming the micro lenses, outgas before assembly, etc. is deposited with a thickness of about 300 angstrom. In the second embodiment, in a condition that the organic thin-film layer 50 is deposited on the pad area 17 as shown in the drawing, a process for removing the organic thin-film layer 50 is performed before the dicing process.

FIGS. 6A and 6B are cross sectional views for explaining an organic thin-film layer removing process to the semiconductor wafer 1. In the drawing, similar parts as in FIG. 5 are indicated by the same reference numbers as in FIG. 5.

As shown in FIG. 6A, the organic thin-film layer removing process is executed to the semiconductor wafer 1 to which the dicing process has not been executed yet, by setting the semiconductor wafer 1 to a reduced pressure O₂ plasma chamber. The plasma process is executed under a condition having, for example, a high frequency power source output of 50(W) at 13.56 MHz, a vacuum rate in the chamber for 20 (Torr) and a gas-flow rate at 10 (ml/min). Under this condition, plasma treatment time will be, for example, 10 (sec). Further, a gas used in the plasma process is not limited to the above-described O₂ gas but also be a mixed gas of O₂ and Ar.

By performing the plasma process under the above-described condition, the organic thin-film layer having thickness of about 300 angstrom can be removed, and the metal surface of the pad area 17, which is the surface of the wiring layer 15, will be exposed as shown in FIG. 6B.

By the above-described plasma process, the hydrophilicizing process is simultaneously executed to the micro lenses 32 formed on the solid state imaging device 12. Each of the micro lenses 32 has, for example, a height of about 1 μm and a diameter of about 3 μm. Under the above-described plasma condition, surfaces of the micro lenses 32 are etched about 0.03 μm; however, it is about 3% of the height of the microlenses 32. Therefore, the plasma process has almost no influence on an optical property of the micro lenses 32.

Moreover, under a plasma condition harder than the above-described plasma condition, the process may cause, by a rapid reaction, deteriorations of an optical property of the micro lenses 32 and an electrical property of the solid state imaging device 12 which are influences of the process other than desired influences such as removing the organic thin-film layer 50 which is the objects of the plasma process according to the second embodiment. Therefore, the plasma process according to the second embodiment is necessary to be a low damage plasma condition such as the above-described plasma condition. Here, similar to the first embodiment, the low damage plasma condition is, for example, a condition wherein organic material is not etched more than 300 angstrom.

In the second embodiment, the organic thin-film layer 50 deposited on the pad area 17 is assumed to have a thickness of about 300 angstrom; therefore, the above-described plasma condition is sufficient. Further, according to a measurement executed by the inventors of the present invention, a thickness of the organic thin-film layer 50 deposited on the pad area 17 after forming the micro lenses 32 was in a range of about 250 to 300 angstrom. Therefore, the organic thin-film layer 50 can be almost completely removed by the organic thin-film layer removing process according to the second embodiment of the present invention under the above-described plasma condition.

Moreover, a plasma condition for removing an organic thin-film layer is not limited to the above-described plasma condition, but the plasma treatment time can be varied in accordance with a thickness of the organic thin-film layer deposited on the pad area 17 and used gas can be changed in accordance with a type of deposited materials.

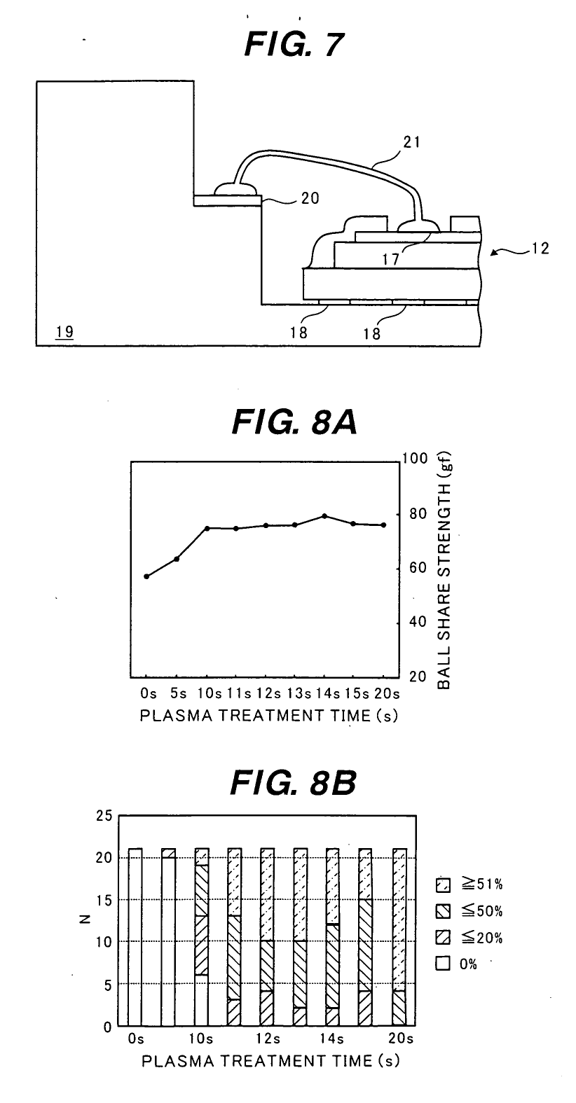

FIG. 7 shows a wire bonding process according to the second embodiment of the present invention.

First, the dicing process that makes the semiconductor wafer 1, of which the organic thin-film layer 50 deposited on the pad area 17 is removed, a plurality of chips, each of which includes one solid state imaging device 12. Next, each chip including the solid state imaging device 12 is fixed to a package 19 made of ceramic, plastic or the likes by silver paste, etc.

Thereafter, a wire bonding process for electrically connecting the package 19 and the solid state imaging device 12 is executed. The wire bonding process is performed by connecting an inner lead area 20 formed in the package 19 and the pad area 17 formed in the solid state imaging device 12 with a wire bonding 21 made of a gold line, an aluminum line, etc. In this second embodiment, because the organic thin-film layer 50 deposited on the pad area 17 has been completely (or almost completely) removed by the above-described organic thin-film layer removing process before this wire bonding process, the metal surface of the wiring layer 15 is exposed at the pad area 17 of the solid state imaging device 12. Therefore, an alloy of the metal surface of the wiring layer 15 and the wire bonding 21 made of a gold line, an aluminum line, etc. used in the wire bonding process will be formed easily, and connection strength can be incredibly improved as compared to the conventional method.

After this wire bonding process, an assembly of a solid state imaging apparatus will be completed by attaching a glass or an optical parts, etc. to the package 19 by well-known processes.

FIGS. 8A and 8B are graphs showing measurement results of connection strength of a wire bonding 21 made of a gold wire after the organic thin-film layer removing process according to the second embodiment of the present invention.

FIG. 8A is a graph showing a relationship between the plasma treatment time and ball share strength according to the second embodiment of the present invention. An abscissa represents the plasma treatment time (second), and an ordinate represents the ball share strength (grams force).

When the plasma treatment time is zero second, that is, when the organic thin-film removing process according to the second embodiment is not performed, the ball share strength of the wire bonding 21 is about 50 (gf) or less.

When the plasma treatment time at the time of the organic thin-film removing process according to the second embodiment is set to 10 seconds, the ball share strength of the wire bonding 21 is improved to about 60 (go to about 70 (gf). Moreover, when the plasma treatment time is set to 11 seconds, as same as the case that the plasma treatment time is set to 10 seconds, the ball share strength of the wire bonding 21 is improved to about 60 (gf) to about 70 (gf).

It is clear from the above that the connecting strength of the wire bonding 21 has been incredibly improved by performing the organic thin-film removing process according to the second embodiment.

FIG. 8B is a graph showing a number of remaining gold on the pad area 17 after the measurement of the ball share strength shown in FIG. 8A. An abscissa represents the plasma treatment time (second), and an ordinate represents a number of samples (N).

When the plasma treatment time is zero second, that is, when the organic thin-film removing process according to the second embodiment is not performed, the number of remaining gold is 0% for every sample. From this, it is considered that the organic thin-film layer 50 is deposited on the pad area 17, and an alloy of the gold line 21 for wire bonding and the pad area 17 has not been formed.

When the plasma treatment time at the time of the organic thin-film removing process according to the second embodiment is set to 10 seconds, all of the numbers of remaining gold are 20% or more except six samples, and almost half of the samples have the numbers of remaining gold that is 50% or more. Moreover, When the plasma treatment time at the time of the organic thin-film removing process according to the second embodiment is set to 11 seconds, there will be no sample having the number of remaining gold that is 0%, and 70% or more samples has the numbers of remaining gold that is 50% or more. From this, it can be considered that the organic thin-film layer 50 is removed from the pad area 17 by performing the organic thin-film removing process according to the second embodiment, and therefore an alloy of the gold line 21 for wire bonding and the pad area 17 has been easily formed.

As described in the above, according to the second embodiment of the present invention, an organic thin-film layer deposited on a pad of a solid state imaging device can be completely (or almost completely) removed by the organic thin-film layer removing process. Moreover, organic thin-film layers in all of solid state imaging devices formed on a semiconductor wafer can be simultaneously removed at one occasion by performing the organic thin-film layer removing process according to the second embodiment before performing the dicing process. Therefore, the second embodiment of the present invention does not harm productivity of the solid state imaging device.

Furthermore, according to the second embodiment of the present invention, the wire bonding process is performed after removing an organic thin-film layer deposited on a pad area of a solid state imaging device and exposing a metal surface of a wiring layer at the pad area; therefore, an alloy of the exposed metal surface of the wiring layer at the pad area and a gold line for wire bonding can be easily formed, and connection strength of the wire bonding can be incredibly improved. Therefore, electrical reliability of the solid state imaging device can be improved.

The present invention has been described in connection with the preferred embodiments. The invention is not limited only to the above embodiments. It is apparent that various modifications, improvements, combinations, and the like can be made by those skilled in the art.

1. A manufacturing method of a solid state imaging apparatus, comprising the steps of:
(a) preparing a semiconductor wafer on which a plurality of solid state imaging devices are formed;
(b) grinding an opposite side of a surface of the semiconductor wafer where the solid state imaging devices are formed; and
(c) dicing the back grinded semiconductor wafer by a dicing blade and removing adhering material appeared by the dicing by performing rinsing that gives a low damage to the solid state imaging device.

2. The manufacturing method of a solid state imaging apparatus according to claim 1, wherein the semiconductor wafer is rinsed by a mega sonic rinsing during the dicing at the dicing step (c).

3. A manufacturing method of a solid state imaging apparatus comprising the steps of:
(a) preparing a semiconductor wafer on which a plurality of solid state imaging devices are formed;
(b) attaching the semiconductor wafer to a dicing ring via a dicing tape;
(c) performing a hydrophilicizing process to the semiconductor wafer attached to the dicing ring and to an adhesive of the dicing tape; and
(d) dicing the hydrophilicized semiconductor wafer by a dicing blade and removing adhering material appeared by the dicing by performing rinsing that gives a low damage to the solid state imaging device.

4. The manufacturing method of a solid state imaging apparatus according to claim 3, wherein the hydrophilicizing process removes at least a part of the adhesive.

5. The manufacturing method of a solid state imaging apparatus according to claim 3, wherein the hydrophilicizing process at the step (c) is a plasma process under a low damage plasma condition for lowering an influence to parts other than the adhesive.

6. The manufacturing method of a solid state imaging apparatus according to claim 5, wherein the low damage plasma condition is a condition wherein organic material is not etched more than 300 angstrom.

7. The manufacturing method of a solid state imaging apparatus according to claim 3, wherein the semiconductor wafer is rinsed by a mega sonic rinsing during the dicing at the dicing step (d).

8. The manufacturing method of a solid state imaging apparatus according to claim 3, further comprising the step of grinding an opposite side of a surface of the semiconductor wafer where the solid state imaging devices are formed before the attaching step (b).

9. The manufacturing method of a solid state imaging apparatus according to claim 8, wherein the hydrophilicizing process removes at least a part of the adhesive.

10. The manufacturing method of a solid state imaging apparatus according to claim 8, wherein the hydrophilicizing process at the step (c) is a plasma process under a low damage plasma condition for lowering an influence to parts other than the adhesive.

11. The manufacturing method of a solid state imaging apparatus according to claim 10, wherein the low damage plasma condition is a condition wherein organic material is not etched more than 300 angstrom.

12. The manufacturing method of a solid state imaging apparatus according to claim 8, wherein the semiconductor wafer is rinsed by a mega sonic rinsing during the dicing at the dicing step (d).

13. A manufacturing method of a solid state imaging apparatus comprising the steps of:
(a) preparing a semiconductor wafer on which a plurality of solid state imaging devices each having a pad area for connecting a wire bonding are formed;
(b) performing an organic thin-film layer removing process for removing an organic thin-film layer disposed on the pad area to the semiconductor wafer;
(c) dicing the semiconductor wafer after the organic thin-film layer removing step (b);
(d) connecting each one of the plurality of the solid state imaging devices diced at the dicing step (c) to a package having an inner-lead area; and
(e) connecting the pad area of each solid state imaging device and the inner lead area of each package by wire bonding.

14. The manufacturing method of a solid state imaging apparatus according to claim 13, wherein the organic thin-film layer removing process at the step (b) is a plasma process under a low damage plasma condition.

15. The manufacturing method of a solid state imaging apparatus according to claim 14, wherein the low damage plasma condition is a condition wherein organic material is not etched more than 300 angstrom.
